(19) United States
(12) Patent Application Publication
(10) Pub. No.: US 2014/0290719 A1
(43) Pub. Date: Oct. 2, 2014

(54) Method Of Fabricating Solar Modules, And Solar Module Obtained Thereby

(71) Applicants: Guy Beaucarne, Oud-Heverlee (BE); Ann Walstrom Norris, Blacksburg, VA (US); Jonathan Govaerts, Gent (BE); Frederic Dross, Deurne (BE)

(72) Inventors: Guy Beaucarne, Oud-Heverlee (BE); Ann Walstrom Norris, Blacksburg, VA (US); Jonathan Govaerts, Gent (BE); Frederic Dross, Deurne (BE)

(21) Appl. No.: 14/237,399

(22) PCT Filed: Jul. 26, 2012
(86) PCT No.: PCT/EP2012/064673

§ 371 Date: May 19, 2014

Related U.S. Application Data
(60) Provisional application No. 61/530,784, filed on Sep. 2, 2011.

(30) Foreign Application Priority Data
Sep. 2, 2011 (GB) 1115223.8

(51) Int. Cl. H01L 31/048; H01L 31/20

(52) U.S. Cl. CPC H01L 31/0487; H01L 31/202
USPC 136/251; 438/67

(57) ABSTRACT

A method of manufacturing a solar module is described. The method enables a semiconductor element to be mounted onto a load-bearing member early on in the manufacturing process without any undesired effects during later processing.

### FIELD OF INVENTION

The present invention relates to a method of fabricating solar modules, and solar modules produced by this method.

### BACKGROUND OF INVENTION

Photovoltaic or solar modules are typically produced by first processing semiconductor wafers into photovoltaic or solar cells, also known as solar module units, and subsequent assembly of these cells into the final solar cell modules by adhesion of the solar cells to a load-bearing member.

However, these routes to manufacture can involve numerous manipulations of the thin, crystalline wafers, which are highly susceptible to breakage either alone or as part-assembled cells to be interconnected. As the photovoltaic industry is driven by a need for ever thinner solar cells and modules containing thinner wafers, this manufacturing problem becomes increasingly relevant.

One assembly method aimed at mitigating this problem relies on transferring the semiconductor wafers to the load-bearing member early on in the solar cell manufacturing process and carrying out subsequent solar cell manipulations with the semiconductor wafer bonded to the load-bearing member. In this way, yield losses and process costs could be reduced.

It is an objective of the present invention to provide alternative or improved methods of manufacturing solar cells and modules.

### SUMMARY OF INVENTION

A first aspect of this invention provides a method of making a solar module, comprising:
providing an optically transparent load-bearing member;
providing at least one semiconductor element;
bonding the at least one semiconductor element to a surface of the optically transparent load-bearing member using an optically transparent adhesive thereby to obtain a part-formed solar module; and
performing a vapour phase deposition treatment at the surface of the load-bearing member which has the at least one semiconductor element bonded thereto, whereby an exposed surface(s) of the at least one semiconductor element and at least a portion of the region of the surface of the load bearing member outside the at least semiconductor element(s) is subjected to said treatment;
wherein the adhesive is applied only at a region or regions which are directly between the optically transparent load-bearing member and the at least semiconductor element.

By restricting the surface coverage of the adhesive only to a region or regions which lie directly between the optically transparent load-bearing member and the semiconductor elements, the adhesive is protected by the load-bearing member and the semiconductor elements during subsequent processing steps and is thus compatible with these subsequent steps. For example, the adhesive is protected from detrimental effects of temperature or chemical reactivity. Thus, the semiconductor elements can be advantageously adhered to the load-bearing member early on in the manufacture of a solar module without any detrimental effect to the adhesive during later processing steps.

A second aspect of the invention provides a solar module obtained or obtainable by the method of the first aspect.

A third aspect of the invention provides a solar module, comprising:
an optically transparent load-bearing member;
at least one semiconductor element bonded by an optically transparent adhesive to a surface of the optically transparent load-bearing member, thereby covering portions of said surface of the optically transparent load-bearing member;
an encapsulant layer encapsulating at least a portion of the at least one semiconductor element;
wherein those parts of said surface of the optically transparent load-bearing member not covered by the at least one semiconductor element are free from said adhesive.

### DETAILED DESCRIPTION OF INVENTION

The present inventors observed that adhesives of the type used to bond semiconductor wafers to glass superstrates in the fabrication of solar cell modules can undergo unexpected and undesired side reactions with subsequent back end processing steps. In particular the present inventors observed that exposed silicone-based adhesive under vapor phase deposition conditions can cause silicone polymer incorporation onto the deposit on the semiconductor wafer, along with a loss of performance of the resulting solar cell module. Similar compatibility problems may also be encountered with other backside treatments such as wet chemical processing or cleaning, for example.

### Load-Bearing Member

The load-bearing member may be in the form of an optically transparent superstrate which is bonded to the light-receiving face of the solar cell thus forming the protective outward-facing surface of the completed module. In this embodiment, light passes through the optically transparent superstrate before reaching the semiconductor wafer. Alternatively, the load-bearing member may be a back layer or substrate bonded to the rear of the solar cell. The photovoltaic module may comprise both a superstrate and a substrate.

The load-bearing member may have a thermal coefficient of expansion (TCE) of a similar order of magnitude to that of the semiconductor wafer to which it is bonded. For example, the load-bearing member may have a TCE below about 10 ppm/K.

The load-bearing member may be sufficiently rigid to support the load of all other components of the photovoltaic module.

In the embodiment where the photovoltaic module comprises an optically transparent superstrate, the superstrate may also serve as a barrier to environmental conditions such as rain, dirt, UV light, moisture at the intended site of use.

The optically transparent superstrate may be formed, for example, from glass, ceramic, or plastic. However, any other suitable load-bearing light-transmissive material may be used.

### Semiconductor Element

The solar or photovoltaic cells made by the method of the present invention may comprise semiconductor elements in the form of wafers of semiconductor material. Suitable materials include, but are not limited to, crystalline or polycrystalline silicon, gallium arsenide, copper indium diselenide, cadmium telluride, copper indium gallium dieselenide, or mixtures including any one or more thereof.

The wafer is prepared by any known method in the art. Typically, semiconductor wafers are prepared by mechanically sawing a thin layer, i.e. the wafer, from a single crystal or bulk multicrystal ingot.

Alternatively, the semiconductor element may be in the form of a thin foil or film. The thin foil may be prepared by any known method in the art. For example, the thin foil or film may be formed by growing epitaxially a monocrystalline layer of silicon on a mono-crystalline seed-substrate, for example a silicon wafer, and then transferring this material to the load-bearing member.

If required, any front side processing steps may be carried out before the wafer is cleaved from the bulk material. Alternatively, any front side processing may be carried out after the wafer or foil has been cleaved from the bulk material. In this embodiment, the wafer or foil may be transiently supported on its rear face so that it is stably positioned during front side processing. Front side processing refers to any process steps performed at the outwardly directed surface of the semiconductor wafer which will face the light source in use.

Examples of such front side processing steps include surface texturing and/or providing a front surface field, and/or providing an antireflection coating. Front side processing may be carried out on a plurality of semiconductor substrates simultaneously. Front side processing may comprise a vapour phase deposition under vapour phase conditions. For example, front side processing may comprise deposition of a layer of amorphous silicon. The vapour phase deposition may comprise plasma enhanced chemical vapour deposition (PECVD).

### Adhesive

As described above, in this invention, the adhesive is applied only at a region or regions which lie directly between the optically transparent load-bearing member and the at least semiconductor element. For the avoidance of doubt, said region or regions may extend up to a peripheral edge of the at least one semiconductor element, or may stop short of said peripheral edge. For example, the region may be a single region which is coextensive with the at least semiconductor element. Alternatively, at least one region of adhesive may be provided which extends to a position inward of the peripheral edge of the at least semiconductor element.

The adhesive serves to bond the semiconductor wafer, for example a silicon wafer, to the load-bearing member. As described above, the load-bearing member is typically an optically transparent superstrate through which light passes before it reaches the solar cell. The adhesive is optically transparent when set, dried, cured, or otherwise transformed from the initial, normally liquid state in which it is applied to its final state in which it serves to bond the semiconductor elements to the load bearing member.

The adhesive may be any material known in the art which demonstrates good adhesive properties to both the semiconductor wafer and the load-bearing member to which it is to be bonded, for example an optically transparent superstrate, and which is optically transparent when set, dried or cured.

Since light must pass through the optically transparent superstrate and adhesive when the solar module is in use, the term optically transparent will be understood to mean that the superstrate and adhesive are transparent to the wavelengths of light which will be absorbed by the solar cell. The optically transparent superstrate and adhesive may have matched refractive indices in order to minimize reflection. The adhesive may have a refractive index intermediate to the refractive index of the optically transparent superstrate and the solar cell. The solar cell may be provided with an anti-reflection coating. The adhesive may thus have a refractive index intermediate to the refractive index of the anti-reflection coating.

The adhesive may be deposited onto the semiconductor wafer, or on the region of the surface of the load-bearing member which will align with the semiconductor wafer. The adhesive may be a liquid-based adhesive which can be cured, set or dried.

The adhesive may be cured, set or dried in situ on the component of the solar module to which it has been applied. The adhesive may be cured, set or dried in situ on the component of the solar module to which it has been applied prior to contact with the second component to which it is to bond. The adhesive may be cured, set or dried in situ on the semiconductor wafer prior to wafer placement on the load-bearing member, for example an optically transparent superstrate. The adhesive may be cured, set or dried in situ on the load-bearing member, for example an optically transparent superstrate, prior to placement of the semiconductor wafer on the load-bearing member.

Alternatively, the adhesive may be cured in situ after the semiconductor wafer has been aligned on the load-bearing member. Alternatively, the adhesive may be cured in situ after the semiconductor wafer has been aligned on the load-bearing member and following any subsequent back-end processing steps.

The adhesive may be cured, set or dried according to the nature of the adhesive being used. For example, the adhesive may be UV, IR or thermally cured. The adhesive may be cured at low temperatures, for example less than 200° C., for example less than 80° C. Alternatively, the adhesive may be cured using a peroxide initiator.

The adhesive may be a silicone-based adhesive. The silicone-based adhesive may be any suitable silicone-based material known in the art. Examples of suitable adhesives include but are not limited to the PV Series encapsulants from Dow Corning, for example Silicone PV6010, Silicone PV6100 and Silicon PV6120.

The adhesive may be applied to the first surface of the load-bearing member or to the front-facing surface of the semiconductor element by any known means, for example spin coating, dip coating, curtain coating, extrusion coating and spray coating, blade coating, screenprinting or stencilprinting, jetting and dispensing.

The viscosity of the adhesive composition may be no greater than 50000 mPa·s when measured at 25° C., more preferably no greater than 40000 mPa·s. The viscosity of the adhesive composition may be no greater than about 10000 mPa·s when measured at 25° C., for example no greater than about 6000 mPa·s. Viscosity was measured using a Brookfield cone/plate rheometer (LVF No 3 Model) at 25° C. and 60 rpm.

The adhesive may be applied in as thin a layer as is required to provide sufficient adhesion. The layer of adhesive may be less than about 200 μm in thickness, for example less than about 150 μm, for example less than about 100 μm. The layer of adhesive may be less than about 50 μm in thickness, for example about 30 μm, for example about 20 μm. The layer of adhesive may be from about 20 μm to about 200 μm in thickness.

### Vapour Phase Deposition Treatment

The vapour phase deposition treatment may be used to apply a passivating layer to the back side of the solar module under fabrication. For example, a passivating layer of intrinsic or doped amorphous silicon may be applied by vapour phase deposition.

The passivating layer may be deposited under plasma enhanced chemical vapour deposition (PECVD) conditions. Thus, by way of example, a layer of amorphous silicon may be deposited under plasma enhanced chemical vapour deposition conditions.

The vapour phase deposition treatment may be used to form a base-emitter junction such as an emitter layer before providing an encapsulation layer. Thus, once the semiconductor element has been bonded to the load-bearing member, an emitter layer may be applied by vapour phase deposition to the back end of the solar module under fabrication. In one embodiment a layer of amorphous silicon is deposited.

The emitter layer may be deposited under plasma enhanced chemical vapour deposition (PECVD) conditions. Thus, by way of example, a layer of amorphous silicon may be deposited under plasma enhanced chemical vapour deposition conditions.

The vapour phase deposition treatment may be used to form a back surface field layer before providing an encapsulation layer. Thus, once the semiconductor element has been bonded to the load-bearing member, a back surface field layer may be applied by vapour phase deposition to the back end of the solar module under fabrication. In one embodiment a layer of amorphous silicon is deposited.

The back surface field layer may be deposited under plasma enhanced chemical vapour deposition (PECVD) conditions. Thus, by way of example, a layer of amorphous silicon may be deposited under plasma enhanced chemical vapour deposition conditions.

The vapour phase deposition treatment may be carried out directly after the semiconductor elements have been bonded to the load bearing member, without any intervening back treatments other than cleaning treatments of the module having been carried out.

### Cleaning Treatments

Prior to any back end processing steps, the module may be cleaned. It has been observed that not all chemical cleaning treatments are compatible with silicone based adhesives, and that the silicone is degraded by certain treatments.

Thus, the adhesive may be incompatible with the vapour phase deposition and/or with the chemical cleaning treatment. A suitable cleaning treatment may comprise a hydrofluoric acid based treatment. Other suitable chemical cleaning treatments may comprise one or more of the treatments listed in Table 2.

### Other Back End Processing Steps

Back end processing or rear side processing refers to any manufacturing steps carried out on the surface of a semiconductor element which faces away from the sunlight when in operation.

Additional back end process steps which may be carried out include providing a window in an emitter layer to contact the underlying base layer, depositing and patterning an insulation layer and formation of a back surface field at the base contacts.

Optionally, an encapsulant layer may be applied to the back end of the solar module under fabrication. The encapsulant layer may comprise a silicone-based material of the type discussed above in connection with the adhesive.

The third aspect of this invention defines an encapsulated solar module of the invention. The encapsulation may be carried out in accordance with, for example, the teachings of WO 2005/006451, the contents of which are incorporated herein by reference.

### Method of Solar Module Fabrication

The method of the invention may be advantageously applied to the simultaneous or continuous preparation of a plurality of solar cell units positioned on a single load-bearing member, for example an optically transparent glass superstrate. In this way, all subsequent back-end processing steps can be advantageously carried out simultaneously on a single component.

If required, the surfaces of the semiconductor element and the load-bearing member, for example a glass superstrate, are cleaned and prepared before use. For example, the surfaces may be treated with a hydrofluoric acid solution.

Optionally, any front-side processing of the semiconductor element is then carried out. Examples of such front side processing steps include surface texturing and/or providing a front surface field, and/or providing an antireflection coating. Front side processing may be carried out on a plurality of semiconductor substrates simultaneously. Front side processing may comprise a vapour phase deposition under vapour phase conditions. For example, front side processing may comprise deposition of a layer of amorphous silicon. The vapour phase deposition may comprise plasma enhanced chemical vapour deposition (PECVD).

Next, the semiconductor element is bonded to the load-bearing member, for example a glass superstrate, using an adhesive of the type described previously.

If the adhesive composition is applied to the front facing surface of the semiconductor element, the adhesive may be applied by any method mentioned previously. The entire surface of the semiconductor element may be coated with adhesive. Alternatively, only a region of the surface of the semiconductor element is coated with adhesive.

Alternatively, the adhesive is applied to the first surface of the load-bearing member. In the embodiment in which the load-bearing member is a glass superstrate which will become the outer layer of the solar module, the first surface will be the rearward facing surface. A small amount of the adhesive may be applied within the region of the first surface of the load-bearing member which will align with the semiconductor element.

The adhesive may be applied to both the semiconductor element and the first surface of the load-bearing member.

In order to ensure good adhesion between the adhesive and the semiconductor element and between the adhesive and the load-bearing member, the adhesive may optionally be degassed before being set, cured or dried. Degassing of the adhesive ensures that there are no pockets of moisture remaining in the adhesive which could have an adverse effect on the efficiency of the photovoltaic device during operation.

Degassing of the adhesive may be effected by subjecting the semiconductor element and/or the load-bearing member to which the adhesive has been applied to an environment of reduced pressure. For example, good bubble-free wet-out of the adhesive can be achieved by applying a vacuum before curing, setting or drying the adhesive.

The adhesive may be cured, set or dried when in contact with only one of the semiconductor element and the load-bearing member. In other words, the adhesive may be cured, set or dried with its upper surface exposed to the environment. In this embodiment, once the adhesive has been cured, set or dried, the other of the semiconductor element and the load-bearing member is then bonded to the cured, set or dried adhesive.

Alternatively, the adhesive may be cured, set or dried after it is contacted with both the semiconductor element and the load-bearing member. In other words, adhesive is applied to one or both of the semiconductor element and the load-bearing member, the semiconductor element and the load-bearing member are aligned together such that a single layer of adhesive is sandwiched between them and then the adhesive is cured, set or dried.

In this embodiment, the amount of adhesive used to bond each semiconductor element to the load-bearing member may be sufficient to provide good adhesion, but not so much that there is an egress of adhesive from between the two materials.

Conversely, the adhesive layer may be in contact with the entire surface of the semiconductor wafer to maximise adhesion to the load-bearing member. Following bonding of the semiconductor wafer to the load-bearing member, an inspection of the bonding may be carried out to ensure that the adhesive contacts the semiconductor wafer on its entire front facing surface with no voids around the edges. Further adhesive may be backfilled between the semiconductor wafer and load-bearing member.

The exact nature and duration of the curing, setting or drying step will vary depending on the nature of the adhesive used. The adhesive may be thermally cured, set or dried at low temperatures, for example less than about 200° C., or less than about 100° C. The adhesive may be thermally cured, set or dried at a temperature of less than about 80° C.

Subsequent treatment of the exposed surfaces of the semiconductor elements may take place once each semiconductor element has been bonded to the load-bearing member and the adhesive has been cured, set or dried. In the embodiment wherein the load-bearing member is a glass superstrate, subsequent treatment of the exposed surfaces may generally be referred to as back-end processing.

Treatment of the exposed surfaces of the semiconductor elements comprises a vapor deposition treatment step under vapor deposition conditions. The vapor deposition treatment may comprise a plasma enhanced chemical vapor deposition step. In one embodiment, the plasma enhanced vapor deposition step may comprise deposition of a layer of amorphous silicon.

The adhesive layer is masked from the rear side processing steps by the glass superstrate and the at least one semiconductor element. The adhesive layer may be masked from the PECVD treatment by the glass superstrate and the at least one semiconductor element.

### BRIEF DESCRIPTION OF THE FIGURES

The present invention will now be described by way of example only and without limitation with reference to the following FIGURE, in which:

FIG. 1 shows a schematic of a fabrication process according to the method of the invention.

It will be understood that the following example is merely one embodiment of the invention and that additional front and rear side processing steps may also be carried out to produce a functioning solar cell module, and that any materials specified are by way of example only. However, any modifications to the example described are within the wherewithal of those skilled in the art.

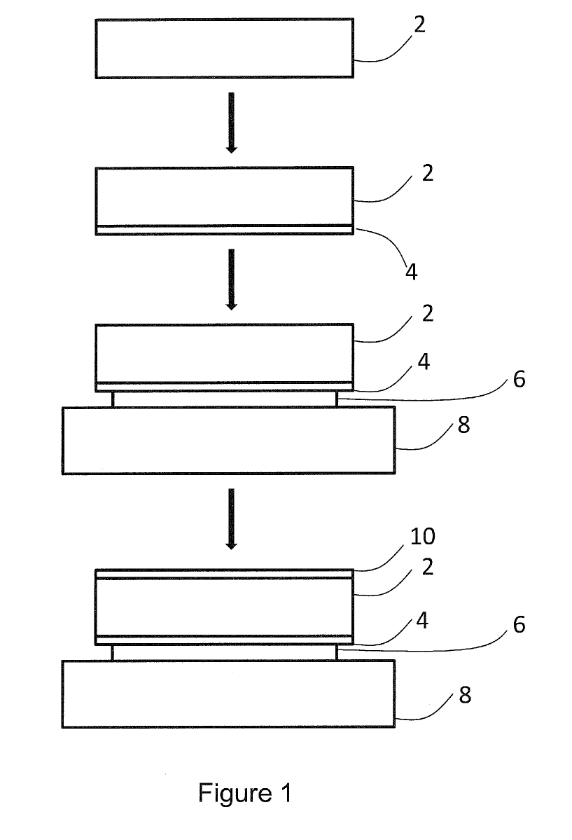

As shown in FIG. 1, semiconductor wafer 2, of a first dopant type, is provided on its front surface with a layer of amorphous silicon 4 which may serve as an n+ front surface field. The amorphous silicon layer may be deposited under vapour phase deposition conditions, though other deposition processes may also be suitable. A passivating intrinsic layer can be also deposited before the doped n+ amorphous silicon layer (not shown). Examples of PECVD conditions for deposition of an intrinsic and n+ layer of amorphous silicon are given in Table 1.

Optionally, wafer 2 may be cleaned using a hydrofluoric acid solution prior to deposition of the intrinsic and n+ front surface field. Wafer 2 may be cleaned using an RCA clean or an Imec clean prior to deposition of the intrinsic or n+ front surface field. Wafer 2 may also be provided with an anti-reflective coating (not shown) prior to deposition of the intrinsic or n+ front surface field.

A layer of silicone adhesive 6 is then used to bond the front surface of the semiconductor wafer to glass superstrate 8. As can be seen in the FIGURE, the adhesive is only in contact with the region of the glass superstrate that aligns with the semiconductor wafer. In order to ensure maximum adhesion, the adhesive may be applied as a liquid formulation to the entire front surface of the semiconductor wafer and cured, set or dried before being bonded to glass superstrate 8. In this way, the need for any backfilling of adhesive into any voids between the edges of semiconductor wafer 2 and glass superstrate 8 can be avoided.

Once the pre-cured formulation of adhesive 6 has been applied to the surface of semiconductor wafer 2, the system may be subjected to reduced pressure in order to degas adhesive 6. For example, the system may be subjected to a pressure of less than about 100 Pa.

As a final step, a plasma enhanced chemical vapor deposition (PECVD) treatment provides a back end layer of amorphous silicon 10 which serves as a p+ or n+ region. A passivating intrinsic layer can be also deposited before the doped amorphous silicon layer (not shown). This PECVD treatment may be preceded by a cleaning step using, for example, a hydrofluoric acid solution, or an RCA or Imec clean. The plasma enhanced chemical vapor deposition may be carried out at a temperature less than about 250° C. Examples of PECVD conditions for deposition of an intrinsic, n+ and p+ layer are given in Table 1.

TABLE 1
PECVD conditions

| | n+ a-Si | intrinsic a-Si | p+ a-Si |
|---|---|---|---|
| | deposition | deposition | deposition |
| Temperature (° C.) | 250 | 250 | 250 |
| Pressure (mTorr) | 525 | 525 | 700 |
| SiH₄ flow (sccm) | 100 | 100 | 50 |
| PH₃ flow (sccm) | 100 | N/A | N/A |
| B₂H₆ flow (sccm) | N/A | N/A | 100 |
| Power (W) | 15 | 15 | 8 |
| Ignition Power (W) | 15 | 15 | 8 |
| Time (sec) | 30 | 30 | 60 |

Subsequent conventional rear side processing may include one or more of deposition of an electrically insulating layer such as a silicon oxide or silicone layer, etching of the electrically insulating layer and amorphous silicon layer 10 to open a window to semiconductor base layer 2 and forming rear side contacts for electrically interconnecting the plurality of cells. Subsequent conventional rear side processing may include for example the use of chemical mixtures indicated in Table 2 which gives a brief summary of the chemical treatments that do not affect the silicone adhesive PV 6100.

TABLE 2
List of the chemical treatments related to the intended full module
process flow that do not affect the silicone adhesive PV6100

| Mixture | Concentration ratio | Time (min) |
|---|---|---|
| Developer:H₂O | 1:4 | 1 |
| BHF | 1 | 10 |
| HF:HNO₃ | 1:80 | 3 |
| acetone | 1 | 10 |
| IPA | 1 | 10 |
| HF:HCl:H₂O | 1:1:40 | 1 |
| HF:HNO₃:H₂O | 1:40:16 | 5 |
| BHF:HNO₃:H₂O | 1:40:16 | 1 |
| TMAH:H₂O | 1:24 | 10 |
| microstrip | 1 | 5 |
| HF:HCl:HNO₃ | 1:8:80 | 5 |
| H₂O₂:HCl:H₂O | 1:1:5 | 10 |

One standard chemical mixture for cleaning, a sulphuric-peroxide mixture (SPM, H₂O₂:H₂SO₄ 1:4) attacks the silicone and cannot be used. Instead an HF dip or other treatment from Table 2 may be used, or if needed the top silicon surface (few μm) can be etched to reveal a pristine surface, using a so called poly-etch solution (BHF:HNO₃:H₂O 1:40:16).

The number and nature of any rear side processing steps will depend on the particular structure of the solar cell modules being fabricated but are within the wherewithal of those skilled in the art.

### EXAMPLES

### Example 1

A solar module unit was prepared in accordance with the general procedure outlined above, with Dow Corning PV encapsulant PV6100, a silicone based adhesive, used to bond a part of the surface area of a silicon wafer to a glass substrate. 200 μm thick n-type CZ (Czochralski) silicon wafers were used.

The flow for preparing the samples is the following: starting from a cleaned wafer, the front is first passivated with a 35 nm intrinsic amorphous silicon layer deposited by PECVD (see conditions in Table 1) and a protective oxide is grown on both sides (wet chemical by immersion in HCl:H₂O₂:H₂O). Then the sample is bonded to glass fully coated with silicone PV6100 (applied by blade coating). After curing the silicone the protective oxide is removed in HF and a second 35 nm intrinsic amorphous silicon layer is deposited on the backside by PECVD. An evaluation has been made by QSSPC (Quasi-Steady-State PhotoConductance) mapping. As a comparison, a solar module unit was prepared in which the entire surface area of a glass substrate was coated with Dow Corning PV encapsulant PV6100 and a silicon wafer bonded to the silicone covered glass. A 35 nm passivating intrinsic layer of amorphous silicon was similarly deposited by PECVD.

Lifetime measurements of both solar module units demonstrated a greater lifetime for the unit prepared in accordance with the method of the invention (1050 μs by QSSPC at injection level 10¹⁵ cm⁻³) compared to the comparative example (45 μs by QSSPC at injection level 10¹⁵ cm⁻³).

These lifetime values for the unit prepared in accordance with the method of the invention are comparable to those measured on a freestanding silicon wafer.

### Example 2

A similar flow has been followed as in previous described tests but with a stack of 7 nm intrinsic/7 nm p+ amorphous silicon layers deposited by PECVD (see conditions in Table 1) on front and backside of 280 μm thick high quality FZ (float zone) silicon wafers. The saturation current values Jₒₑ obtained for the unit prepared in accordance with the method of the invention are comparable to those measured on a freestanding silicon wafer Jₒₑ values (down to 30 to 40 fA/cm²).

X-Ray Photoelectron Spectroscopy measurements on the comparative example showed that there was redeposition on the wafer of short siloxane molecules that had been incorporated from the silicone exposed during the plasma deposition step, which is believed to contribute to the reduced photoconductance value.

A viable method for bonding semiconductor wafers to an optically transparent superstrate early on in the overall fabrication process for solar modules has therefore been demonstrated, with the production of coated solar module units which exhibit lifetime values comparable to those expected on a freestanding wafer. Furthermore, it has been demonstrated that there are no adverse effects on the adhesive when it is subjected to subsequent rear side processing.

The foregoing broadly describes the present invention without limitation to particular embodiments. Variations and modifications as will be readily apparent to those skilled in the art are intended to be within the scope of the invention as defined by the following claims.

1. A method of making a solar module, comprising:
providing an optically transparent load-bearing member;
providing at least one semiconductor element;
bonding the at least one semiconductor element to a surface of the optically transparent load-bearing member using an optically transparent adhesive thereby to obtain a part-formed solar module; and
performing a vapour phase deposition treatment at the surface of the load-bearing member which has the at least one semiconductor element bonded thereto, whereby an exposed surface(s) of the at least one semiconductor element and at least a portion of the region of the surface of the load bearing member outside the at least one semiconductor element(s) is subjected to said treatment;
wherein the adhesive is applied only at a region or regions directly between the optically transparent load-bearing member and the at least one semiconductor element.

2. A method according to claim 1, wherein a plurality of semiconductor elements are provided and which are bonded to the surface of the load-bearing member at spaced apart regions thereon.

3. A method according to claim 1, wherein the adhesive is applied to a first surface of the optically transparent load-bearing member and/or to the at least one semiconductor element.

4. A method according to claim 3, wherein the adhesive is cured, set or dried before contacting the other of the first surface of the optically transparent load-bearing member and/or to the at least one semiconductor element.

5. A method according to claim 1, wherein the adhesive is degassed before being cured, set or dried.

6. A method according to claim 1, wherein the optically transparent load-bearing member comprises a glass superstrate.

7. A method according to claim 1, wherein the at least one semiconductor element comprises a semiconductor wafer.

8. A method according to claim 7, wherein the semiconductor wafer is formed from polycrystalline silicon or single crystal silicon.

9. A method according to claim 1, wherein the vapour phase deposition treatment comprises a vapour phase deposition of an amorphous silicon layer.

10. A method according to claim 1, wherein the adhesive is incompatible with the vapour phase deposition conditions.

11. A method according to claim 10, wherein the adhesive is a silicone adhesive.

12. A method according to claim 1 further comprising, after the treatment step, one or more of the following steps: etching, lithographic treatment, local removal of deposited layers, printing, attachment of electrical contacts, encapsulation.

13. A solar module obtained by the method of claim 1.

14. A solar module, comprising:
an optically transparent load-bearing member;
at least one semiconductor element bonded by an optically transparent adhesive to a surface of the optically transparent load-bearing member, thereby covering portions of said surface of the optically transparent load-bearing member;
an encapsulant layer encapsulating at least a portion of the at least one semiconductor element;
wherein those parts of said surface of the optically transparent load-bearing member not covered by the at least one semiconductor element are free from said adhesive.

15. A method according to claim 2, wherein the plurality of semiconductor elements comprises a plurality of semiconductor wafers.

16. A method according to claim 15, wherein the plurality of semiconductor wafers are formed from polycrystalline silicon or single crystal silicon.
